(19) United States
(12) Patent Application Publication
(10) Pub. No.: US 2007/0079212 A1
(43) Pub. Date: Apr. 5, 2007

(54) Techniques for efficient error correction code implementation in a system

(75) Inventors: Dror Har-Chen, Raanana (IL); Phil Leichty, Rochester, MN (US); Ariel Cohen, Cupertino, CA (US); Oran Uzrad-Nali, Cupertino, CA (US)

Correspondence Address: SUGHRUE MION, PLLC, 2100 PENNSYLVANIA AVENUE, N.W., SUITE 800, WASHINGTON, DC, 20037, US

(73) Assignee: SILVERBACK SYSTEMS, INC.

(21) Appl. No.: 11/395,324

(22) Filed: Apr. 3, 2006

Related U.S. Application Data
(60) Provisional application No. 60/667,093, filed on Apr. 1, 2005.

(51) Int. Cl. H03M 13/00

(52) U.S. Cl. 714/758

(57) ABSTRACT

A memory system with folding error correction. The memory comprises a first memory bank and a second memory bank. A means for generating error correction code for data to be written to said memory system is provided. A means for writing said received data to a location in said first memory bank corresponding to a received address of said received data is provided. Further, a means for generating an error correction code write address in said second memory bank based on said received address. Still further, a means for writing said error correction code to said error correction code write address is provided.

### CROSS-REFERENCE TO RELATED PATENT APPLICATIONS

This application claims priority from U.S. provisional patent application Ser. No. 60/667,093 filed on Apr. 1, 2005, and which is hereby incorporated by reference for all that it contains.

### TECHNICAL FIELD

This disclosure relates generally to memory devices and more particularly to memory devices with embedded error correction codes.

### BACKGROUND

### References

The following U.S. patents and papers provide useful background information, for which they are incorporated herein by reference in their entirety.

A) Patents

| | | |
|---|---|---|
| 6,799,293 | September 2004 | Peters et al. |
| 5,740,188 | April 1998 | Olarig |

Published Applications

| | | |
|---|---|---|
| 20040205433 | October 2004 | Gower |
| 20030002466 | January 2003 | Peters et al. |
| 20020178325 | November 2002 | Allingham |

Data protection is a key component in system design, and specifically so within memory devices. Typically, this is part of the protection means against soft errors in such devices. A soft error is not a result of a defect or permanent damage to a device, but rather an error that, in the case of memory, if re-written to, or corrected by means of error correction, the soft error is overcome. Different mechanisms are used to handle soft error data corruption. Some of these mechanisms aim at merely the detection of an error. Examples for such detection are a multitude of parity based solutions. Another class of solutions provides one or another level of correction, for example, the error correction code (ECC) approach. Any one of these techniques uses a code to define the detection/correction information, and such code requires storage space in memory making it ready for usage as may be necessary. In some implementations a hardware implementation of an algorithm is used for error recovery.

In related art solutions, code storage requirements are addressed in several ways. For example, a SRAM device may include additional memory space, by providing an additional bit per byte, supporting both parity and ECC code storage within the SRAM itself. A typical DRAM device does not include such extra storage but is commonly used in large quantities in a plurality of applications. Notably, most of the DRAM devices consumed are used in personal computers (PCs) main memory and the memory for graphics devices, such as graphics accelerators used in PCs. From the two types of applications the PC main memory is the one which is more sensitive to errors and therefore error handling for that application is of paramount importance.

The typical PC memories are Dual Inline Memory Modules (DIMMs) which are designed out of dense 8-bit wide components. Therefore to design a 64-bit wide PC memory, 8 devices are required. If ECC is implemented, an additional and identical 8-bit device can be added. This allows for an efficient design since the ECC part cost is entirely justified as it is fully occupied while providing the protection. However, in embedded systems, such as an HBA, where space is limited, the system is designed to save footprint by using denser memories. In the case where the available memories in the market are sufficiently dense, the number of components used for the embedded system can be reduced. Not only will that save on precious footprint space but will also result in the reduction of the bill of materials (BOM) for a given implementation.

By means of example, one may consider a memory having a 64-bit interface requiring X mbits. There are several options to achieve this density: eight 8-bit wide devices of X/8 mbits, four 16-bit wide devices of X/4 mbits, or, two 32-bit wide devices of X/2 mbits. Once the system is designed with either 16- or 32-bit wide parts, an 8-bit wide part for the additional storage required for ECC cannot be added. The reason preventing such addition is that the row and column addressing, being different in the different devices, prevents the memory controller from accessing simultaneously all types of memory architectures in a correct manner. As a result, a device matching the other devices must be used, resulting in significant inefficiency. This is simply because the ECC code per matching data word requires only 8-bits out of 16- or 32-bits available, or an efficiency of 50% or 25% respectively. Effectively, the BOM is increased for no good reason due to this inefficiency. An example of such a prior art organization in a unified data and ECC path is shown in FIG. 1. ECC logic 120 is part of the data path to and from memory interface 130, using the same physical memory for ECC as for the rest of the 64 bits. It can also be observed, that each read path includes a delay locked loop (DLL) to shift the incoming data strobe (DQS) by the proper phase, later serving as a clock to latch the incoming data. In addition read DLLs of memory interface 130, there are three more DLLs 150: shifting outgoing DQS, shifting the outgoing flip-flops clock, and detecting the DLL setting. A double data rate (DDR) memory controller 110 controls the data moved in and out from the memory.

Due to the limitations of related art solutions it would be beneficial to provide a solution whereby the use of higher density memory components requiring ECC support, will not result in significant inefficiencies of utilization.

### SUMMARY

To overcome some of the problems noted above, the disclosed teachings provide a memory system with folding error correction. The memory comprises a first memory bank and a second memory bank. A means for generating error correction code for data to be written to said memory system is provided. A means for writing said received data to a location in said first memory bank corresponding to a received address of said received data is provided. Further, a means for generating an error correction code write address in said second memory bank based on said received address. Still further, a means for writing said error correction code to said error correction code write address is provided.

Another aspect of the disclosed teachings is a memory system with folding error correction comprising at least a memory bank. A means for generating error correction code for data to be written to said memory system is provided. A means for writing said received data to a location in said memory bank corresponding to a received address of said received data is further provided. Still further, a means for generating an error correction code write address in said memory bank based on said received address is provided. Still further, a means for writing said error correction code to said error correction code write address is provided.

Yet another aspect of the disclosed teachings is a memory controller with folding error correction comprising a means for accessing a first memory bank. A means for accessing a second memory bank is provided. A means for generating error correction code for received data to be written to said first memory bank is provided. A means for writing said received data to a location in said first memory bank corresponding to a received address of said received data is further provided. A means for generating an error correction code write address in said second memory bank based on said received address is further provided. A means for writing said error correction code to said error correction code write address is further provided.

Still another aspect of the disclosed teachings is a memory controller with folding error correction, the memory controller comprises means for generating error correction code for data to be written to a memory bank. A means for writing said received data to a location in said memory bank corresponding to a received address of said received data is provided. A means for generating an error correction code write address in said memory bank based on said received address is further provided. A means for writing said error correction code to said error correction code write address is further provided.

Still another aspect of the disclosed teachings is a method for placing an error correction code respective of a data received by a memory controller with folding error correction. The method comprises writing said data into a first memory bank of the memory. The error correction code respective of said data is generated. An address in a second memory bank of the memory is generated. The error correction code is written to said address in a second memory bank.

Still another aspect of the disclosed teachings is a method for retrieving data and its respective error correction code of a read address received by a memory controller with folding error correction. The method comprised reading the data from a first memory bank of the memory. An address of a second memory bank of the memory for retrieval of said respective error correction code is generated. The error correction code respective of said data is retrieved. The data read is returned after error correction.

Still another aspect of the disclosed teachings is a method for placing an error correction code respective of a data received by a memory controller with folding error correction. The method comprises writing said data into a memory bank of the memory. The error correction code respective of said data is generated. An address in said memory bank of the memory is generated. The error correction code is written to said address in said memory bank.

Still another aspect of the disclosed teachings is a method for retrieving data and its respective error correction code of a read address received by a memory controller with folding error correction. The method comprises reading the data from a memory bank of the memory. An address in said memory bank for retrieval of said respective error correction code is generated. The error correction code respective of said data is generated. The data read after error correction is returned.

In other aspects of the disclosed teachings, the techniques are incorporated as part of a computer software product. The software product includes computer readable media having a plurality of instructions, which, when executed on a computing machine, perform the techniques disclosed herein.

### BRIEF DESCRIPTION OF THE DRAWINGS

The above objectives and advantages of the disclosed teachings will become more apparent by describing in detail preferred embodiments thereof with reference to the attached drawings in which:

FIG. 1—is a block diagram of a memory controller with ECC support (prior art)

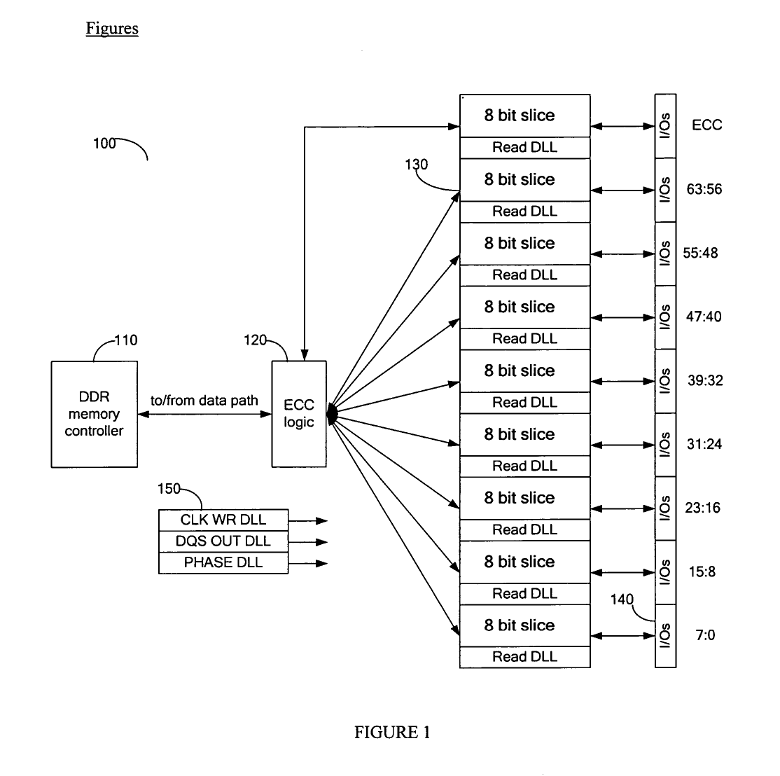

FIG. 2—is a two-bank organization of a memory with ECC folding

FIG. 3—is a sequence of outputting of data and ECC information for a memory with ECC folding

FIG. 4—is a block diagram of a memory controller with ECC folding

FIG. 5—is a same memory bank ECC folding

### DETAILED DESCRIPTION

In accordance with the disclosed teachings there is shown embodiments of a folding error correction code (ECC) for the purpose of including the ECC within the same memory devices rather than adding additional devices as done in prior art solutions. By including the ECC within the same memories, there is achieved the ability to use denser memory devices, including those having wider architectures such as 16- and 32-bits

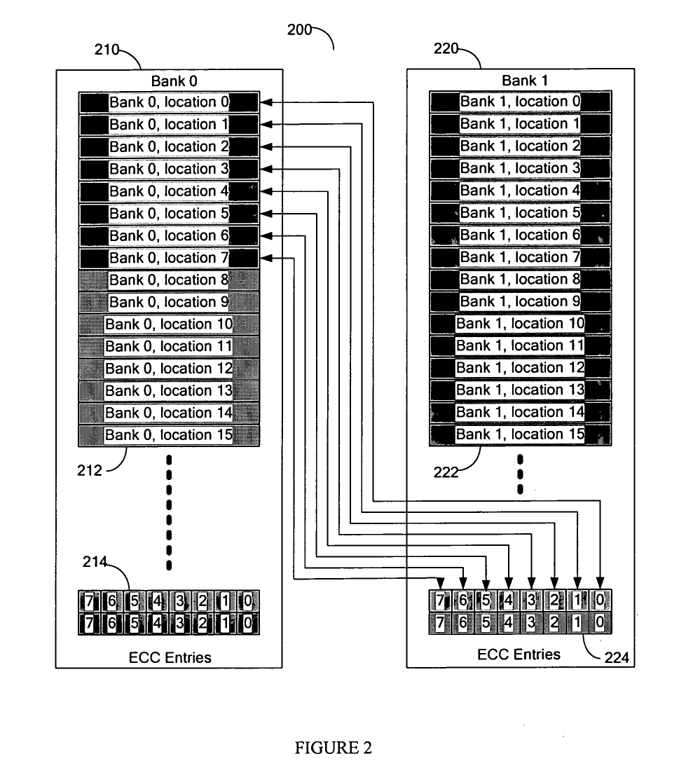

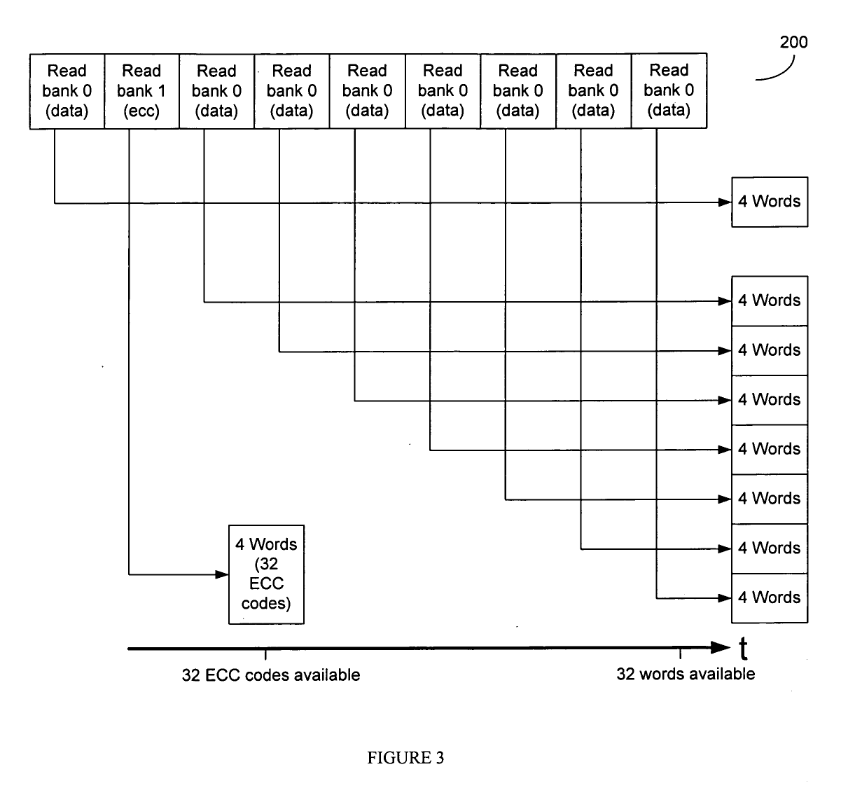

Reference is now made to FIG. 2 where an exemplary and non-limiting two-bank organization 200 of a memory with ECC folding is shown. In accordance with the disclosed teachings the ECC 224 portion respective of a first bank 210 resides in a different bank, for example bank 220, of memory 200. Notably, the solution can work also in cases where there are more than two banks, for example four banks of memory, and then the ECC 224 of a first bank 210 could reside in any one of the other available banks. A sequence of transactions, shown in FIG. 3, can be initiated for the purpose of fetching data and ECC. FIG. 3 shows an exemplary and non-limiting sequence 300 of outputting of data and ECC information for a memory with ECC folding in accordance with the disclosed teachings. The operation begins with an access to memory bank 210 to fetch four words of data. The next access is made to the second bank where the ECC, for example ECC 224, is stored for the purpose of reading that data. Thereafter consecutive read accesses fetch the rest of the data corresponding to ECC 224.

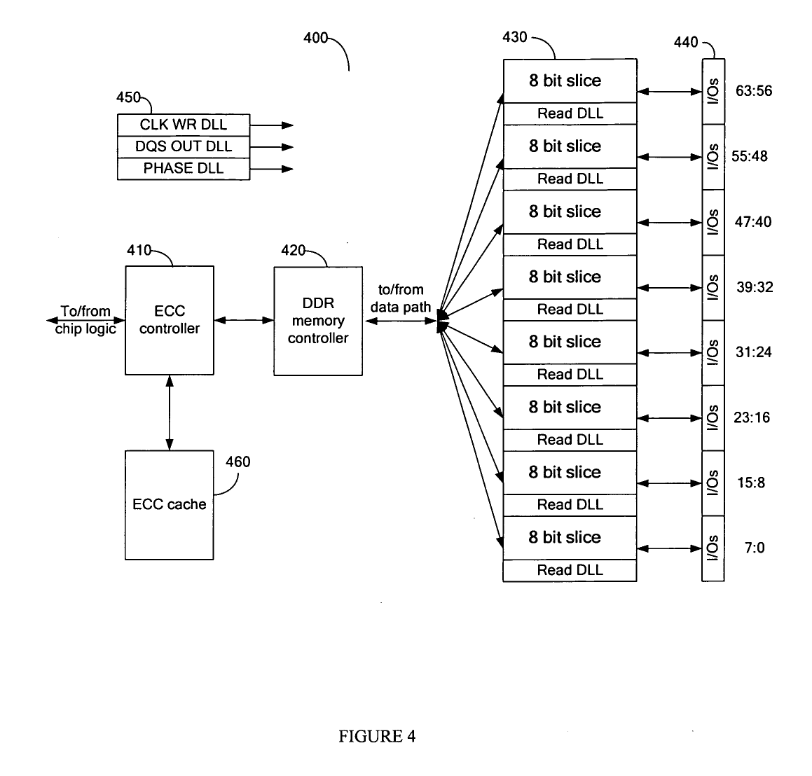

Referring now to FIG. 4 an exemplary and non-limiting block diagram 400 of memory with ECC folding is shown. ECC controller 410 is responsible for the generation of ECC based on the data received in the write operation and sending the data to be stored as explained above. Memory controller 420 performs the actual task of writing data to memory 430. Similarly, during a read operation data is read from the memory 430 using memory controller 420 while ECC controller 410 performs the error detection and error correction as may be necessary. The function of block 450 is the same as the one described for block 150 above. In one embodiment of the disclosed teachings an ECC cache 460 is interfaced to ECC controller 410. In this case it is possible to perform a pre-fetching of ECC data that could be made available for future access of consecutive memory locations. By the time the second data fetch transaction is completed ECC cache 460 will already have the ECC data for the entire request.

The process of reading data in a system in accordance to the system disclosed above involved in ECC controller 410 receiving an address. ECC controller generates the address of the ECC data in the bank where it is located and provides both addresses to memory controller 420. Memory controller generates a read request to a first memory bank to receive the data and to a second memory bank to receive the ECC data. The data is then checked together with its respective ECC information by ECC controller 410. In one embodiment of the disclosed teachings the ECC information is stored in ECC cache 415. In such a case a subsequent access to the same data, if the ECC data is found in ECC cache 415 there is no need to generate an access to a second memory bank to retrieve the ECC data. It is further possible to pre-fetch ECC information in anticipation that future data to be read from a first memory bank, for example memory bank 210, will also require its respective ECC information from a second memory bank, for example memory bank 220. In an equivalent write operation, ECC controller 410 receives an address and a respective data to be written in a first data bank, for example data bank 210. ECC controller 410 generates the ECC information for the respective data and an address for the ECC data, the address placing the data in a second memory bank, for example memory bank 220. Memory controller 420 writes the data using its respective address to a first memory bank, and the respective ECC information into a second memory bank.

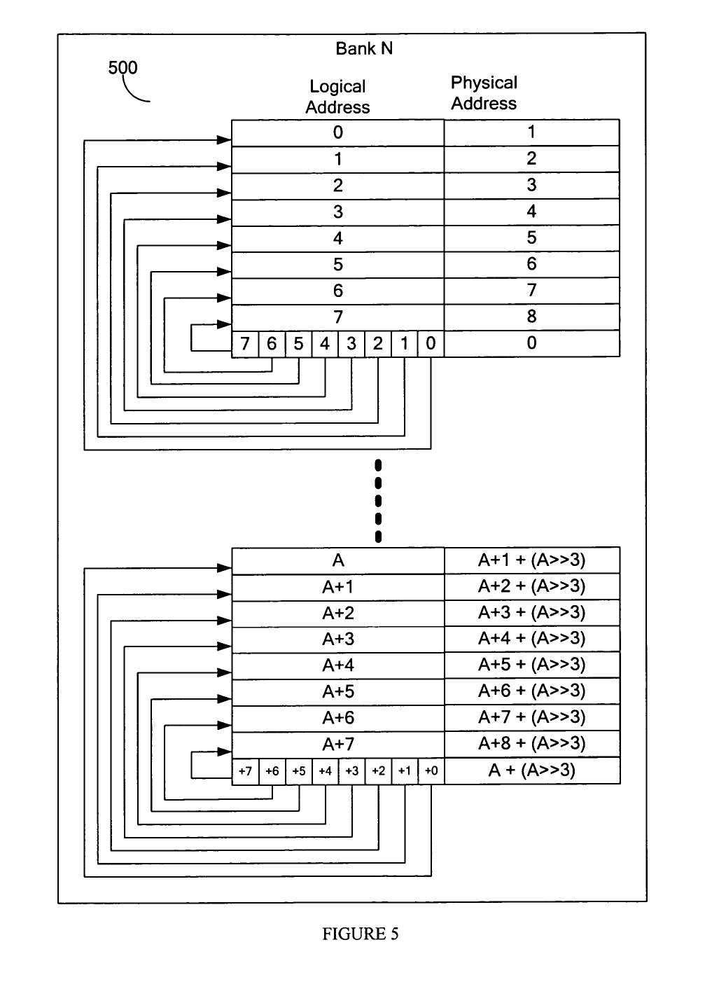

Reference is now made to FIG. 5 where an exemplary and non-limiting same memory bank ECC folding is shown. Specifically, instead of placing the ECC information in a memory bank different from the memory bank of the data, in accordance with this solution, ECC information is placed in memory subsequent to the placement of its respective data. In most of the time ECC information will not only be in the same bank but also in the same column thus avoiding the bank and row activation overhead. FIG. 5 shows that the ECC information, for example for the first eight logical addresses of a memory bank, for example memory bank 500, i.e., address “0” through “7”, is placed in address “8” of the memory bank. The logical address contents column contains the data expected at the logical address listed or the ECC data associated with the preceding data block. In accordance with the disclosed teachings a simple translation of the logical address (A) to the physical address (Ap) is performed, and comprises the function:
Ap=A+(A>>3)+1

The function can be easily accomplished with a single adder by adding the address, shifted right by 3 bits, to itself with carry in. In order to find the physical ECC address (Aep) for a specific logical address (A) a similar simple translation is required, and comprises the function:
Aep=A′+(A′>>3)
where A′ is the address with the 3 least significant bits reset. This function can be easily accomplished with a single adder by adding the address, with its 3 least significant bits reset and shifted right by 3 bits, to itself. A person skilled in the art would note that neither address translation nor the ECC generation and check performed by memory controller 420 and ECC controller 410 have to be exposed to the user.

The length (L) of the transfer would also have to be increased to account for the ECC data by dividing by 8 and multiplying by 9, depicted by the function:
Lp=((L+7)>>3)*9
a function that can easily be implemented using a mere two adders. For performance reasons it may be desirable to cut short the last access thereby skipping over any unused data and issuance of another read of just the ECC data. In that case there would be one read of a length depicted by the function:
Lp=L+(L>>3)
and a second access of length 1.

In another embodiment of the disclosed teachings all the ECC codes of a DRAM column are placed at the end of the column, while maintaining all the data in a consecutive segment. Performance impact is generally negligible since as long as the data and the ECC codes share the same column, no activation is required between the accesses. The difference would be in the address translation only.

The entire translation and ECC operations may be designed to be an internal operation of the system. The advantage over prior art solutions is that the disclosed embodiments allows for the use of ECC in a system using dense memory devices having wide data buses, e.g., data busses of 16-, 32 or 64-bits, or for that matter any number of bits, with good utilization and system cost. This allows for the use of the standard memories without adding special memory to handle the ECC requirements. In comparison to prior art solutions the user will notice a certain decrease in the memory available for use as ECC data uses memory locations that would otherwise be used for data, however, as systems are designed to have excess memory this should not present a problem. As is well-known in the art, typically the commercially available densities of memories (e.g. 256 Mb, 512 Mb, etc.) are larger than the amount of memory that is actually required or used. A person skilled in the art would further note that for debug purposes there is a mode where the address translation and ECC correction would not be done.

A person skilled-in-the-art would appreciate the fact that the teachings disclosed herein can be easily adapted for use with different types of memory devices not having integrated ECC and are therefore hereby included as part of this teachings. In one embodiment of the disclosed invention, the techniques are incorporated as part of a computer software product, including computer readable media, the media comprises a plurality of instructions designed, when executed, to perform the techniques disclosed herein. A person skilled-in-the-art would further note that the entire memory system in accordance with the disclosed teachings may be implemented on a monolithic semiconductor device.

Apart from systems and methods, as noted above, computer program products are also within the scope of the disclosed teaching. These computer program products comprise instructions on a computer readable medium that enable a computer to perform the techniques disclosed herein. The instructions are not limited, and include but not limited to, source code, object code and executables. The computers on which the instructions are implemented include, but not limited to, minis, micros, and mainframes as well as implementations over a network. The computer readable medium includes, but not limited to, floppies, RAMs, ROMs, hard drives, magnetic tapes, cartridges, CDs, DVDs, and internet downloads.

It should be noted that the techniques disclosed can be implemented in any way on a computer. These include, software implementations, hardware implementations or a hardware/software combination. In the software implementation, there is no restriction regarding the choice or level of computer languages.

Other modifications and variations to the invention will be apparent to those skilled in the art from the foregoing disclosure and teachings. Thus, while only certain embodiments of the invention have been specifically described herein, it will be apparent that numerous modifications may be made thereto without departing from the spirit and scope of the invention.

What is claimed is:

1. A memory system with folding error correction, the memory comprising:
a first memory bank;
a second memory bank;
means for generating error correction code for data to be written to said memory system;
means for writing said received data to a location in said first memory bank corresponding to a received address of said received data;
means for generating an error correction code write address in said second memory bank based on said received address; and,
means for writing said error correction code to said error correction code write address.

2. The memory system of claim 1, wherein said memory system further comprises:
means for receiving a read address to said first memory bank;
means for generating an error correction read address from said second memory bank based on said read address;
means for reading data from said first memory bank;
means for reading an error correction data from said second memory bank using said error correction code read address;
means for correcting the data read from said first memory bank based on the error correction code from said error correction read address; and,
means for outputting the corrected data.

3. The memory system of claim 1, wherein said memory is implemented in a monolithic semiconductor device.

4. A memory system with folding error correction, the memory comprising:
at least a memory bank;
means for generating error correction code for data to be written to said memory system;
means for writing said received data to a location in said memory bank corresponding to a received address of said received data;
means for generating an error correction code write address in said memory bank based on said received address; and,
means for writing said error correction code to said error correction code write address.

5. The memory system of claim 4, wherein said memory system further comprises:
means for receiving a read address to said memory bank;
means for generating an error correction read address from said memory bank based on said read address;
means for reading data from said memory bank;
means for reading an error correction data from said memory bank using said error correction code read address;
means for correcting the data read from said memory bank based on the error correction code from said error correction read address; and,
means for outputting the corrected data.

6. The memory system of claim 4, wherein said memory system is implemented in a monolithic semiconductor device.

7. A memory controller with folding error correction, the controller comprising:
means for accessing a first memory bank;
means for accessing a second memory bank;
means for generating error correction code for received data to be written to said first memory bank;
means for writing said received data to a location in said first memory bank corresponding to a received address of said received data;
means for generating an error correction code write address in said second memory bank based on said received address; and,
means for writing said error correction code to said error correction code write address.

8. The memory controller of claim 7, wherein said memory controller further comprises:
means for receiving a read address to said first memory bank;
means for generating an error correction read address from said second memory bank based on said read address;
means for reading data from said first memory bank;
means for reading an error correction data from said second memory bank using said error correction code read address;
means for correcting the data read from said first memory bank based on the error correction code from said error correction read address; and,
means for outputting the corrected data.

9. The memory controller of claim 7, wherein said memory is implemented in a monolithic semiconductor device.

10. A memory controller with folding error correction, the memory controller comprising:
means for generating error correction code for data to be written to a memory bank;
means for writing said received data to a location in said memory bank corresponding to a received address of said received data;
means for generating an error correction code write address in said memory bank based on said received address; and,
means for writing said error correction code to said error correction code write address.

11. The memory controller of claim 10, wherein said memory system further comprises:
means for receiving a read address to said memory bank;
means for generating an error correction read address from said memory bank based on said read address;
means for reading data from said memory bank;
means for reading an error correction data from said memory bank using said error correction code read address;
means for correcting the data read from said memory bank based on the error correction code from said error correction read address; and,
means for outputting the corrected data.

12. The memory controller of claim 10, wherein said memory system is implemented in a monolithic semiconductor device.

13. A method for placing an error correction code respective of a data received by a memory controller with folding error correction, the method comprising the steps of:
writing said data into a first memory bank of the memory;
generating the error correction code respective of said data;
generating an address in a second memory bank of the memory; and,
writing said error correction code to said address in a second memory bank.

14. A computer software product containing a plurality of executable instructions that when executed perform the method of claim 13.

15. A method for retrieving data and its respective error correction code of a read address received by a memory controller with folding error correction, the method comprising the steps of:
reading the data from a first memory bank of the memory;
generating an address of a second memory bank of the memory for retrieval of said respective error correction code;
retrieving said error correction code respective of said data; and
returning the data read after error correction.

16. A computer software product containing a plurality of executable instructions that when executed perform the method of claim 15.

17. A method for placing an error correction code respective of a data received by a memory controller with folding error correction, the method comprising the steps of:
writing said data into a memory bank of the memory;
generating the error correction code respective of said data;
generating an address in said memory bank of the memory; and,
writing said error correction code to said address in said memory bank.

18. A computer software product containing a plurality of executable instructions that when executed perform the method of claim 17.

19. A method for retrieving data and its respective error correction code of a read address received by a memory controller with folding error correction, the method comprising the steps of:
reading the data from a memory bank of the memory;
generating an address in said memory bank for retrieval of said respective error correction code;
retrieving said error correction code respective of said data; and,
returning the data read after error correction.

20. A computer software product containing a plurality of executable instructions that when executed perform the method of claim 19.
